(19) United States
(12) Patent Application Publication
(10) Pub. No.: US 2007/0128842 A1
(43) Pub. Date: Jun. 7, 2007

(54) Method for fabricating semiconductor device

(75) Inventors: Ki-Won Nam, Kyoungki-do (KR); Ky-Hyun Han, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/479,855

(22) Filed: Jun. 29, 2006

(30) Foreign Application Priority Data
Dec. 6, 2005 (KR) 2005-0117943

(51) Int. Cl. H01L 21/469; H01L 21/8234

(52) U.S. Cl. 438/595; 438/770

(57) ABSTRACT

A method for fabricating a semiconductor device includes: forming a plurality of conductive patterns with regionally different densities over a substrate; forming a first insulation layer over the conductive patterns; forming a second insulation layer having substantially the same etch selectivity as the first insulation layer and a better step coverage capability than the first insulation layer over the first insulation layer; oxidizing a predetermined portion of the second insulation layer to form a third insulation layer; and etching the third insulation layer, a remaining portion of the second insulation layer, and the first insulation layer to form spacers over sidewalls of the conductive patterns.

### FIELD OF THE INVENTION

The present invention relates to a method for fabricating a semiconductor device; and more particularly, to a method for fabricating a semiconductor device with uniformly thick spacers.

### DESCRIPTION OF RELATED ARTS

In a lightly doped drain (LDD) spacer structure (i.e., a triple structure of an oxide layer/a nitride layer/an oxide layer) of a peripheral region, as a size of dynamic random access memory (DRAM) has been decreased, if a tetraethylorthosilicate (TEOS) oxide layer is used as a spacer material to be deposited on the top surface to secure a spacer width on sidewalls of a gate electrode, a step coverage property may be weak, and a difference in an etching process condition may be generated.

Furthermore, there may be a difference in a space between a plurality of gate patterns, or in a line size of each gate pattern. As a result, a spacer width may be different in a region where there is the difference in the size of the gate pattern or in the space between the gate patterns. Accordingly, a variation of a threshold voltage in a peripheral region is generated and a device operation margin becomes degraded.

FIG. 1 illustrates a cross-sectional view of a semiconductor device fabricated by a typical method.

A plurality of gate patterns are formed over a substrate 11. The substrate 11 is divided into a region A where the gate patterns are densely disposed and a region B where the gate patterns are loosely disposed. Each of the gate patterns is formed by sequentially stacking a gate insulation layer 12, a gate conductive layer 13, and a gate hard mask (not shown). Gate spacers S are formed on sidewalls of the gate patterns.

The gate spacer S includes a first insulation layer 14, a second insulation layer 15, and a third insulation layer 16. The first insulation layer 14 is an oxide layer. The second insulation layer 15 is a nitride layer. The third insulation layer 16 is an oxide layer. Thus, the gate spacer has an oxide-nitride-oxide (O—N—O) structure.

The first insulation layer 14 has a thickness ranging from approximately 20 Å to approximately 80 Å. The second insulation layer 15 has a thickness ranging from approximately 50 Å to approximately 150 Å. The third insulation layer 16 has a thickness ranging from approximately 300 Å to approximately 700 Å. Tetraethylorthosilicate (TEOS) is an example of an oxide material. Since layers formed in a cell region generally need to be removed except for a layer formed by a light oxidation process at the bottom to open the cell region (e.g., a landing plug contact (LPC) process), the second insulation layer 15 is formed thinner than the third insulation layer 16.

The top oxide layer (i.e., the third insulation layer 16) is removed by using a cleaning solution (e.g., buffered oxide etchant (BOE)), having an etch selectiviy to the nitride layer (i.e., the second insulation layer 15).

As described above, when forming the third insulation layer 16 in the region A and in the region B, the third insulation layer 16 is generally formed more thinly in the region A than in the region B. As a result, there may be a thickness difference between the gate spacers S formed in the region A and in the region B. Accordingly, after performing a subsequent source/drain ion-implantation process, a threshold voltage of a transistor may not be uniform in a peripheral region.

### SUMMARY OF THE INVENTION

It is, therefore, an object of the present invention to provide a method for fabricating a semiconductor device capable of stabilizing a threshold voltage in a peripheral region by reducing a thickness difference in spacers, often caused by gate patterns formed with regionally different densities.

In accordance with one aspect of the present invention, there is provided a method for fabricating a semiconductor device, including: forming a plurality of conductive patterns with regionally different densities over a substrate; forming a first insulation layer over the conductive patterns; forming a second insulation layer having substantially the same etch selectivity to the first insulation layer and a better step coverage capability than the first insulation layer over the first insulation layer; oxidizing a predetermined portion of the second insulation layer to form a third insulation layer; and etching the third insulation layer, a remaining portion of the second insulation layer, and the first insulation layer to form spacers over sidewalls of the conductive patterns.

In accordance with one aspect of the present invention, there is provided a method for fabricating a semiconductor device, including: forming a plurality of conductive patterns having regionally different densities over a substrate; forming a first insulation layer over the conductive patterns; forming a second insulation layer having substantially the same etch selectivity to the first insulation layer and a better step-coverage capability than the first insulation layer over the first insulation layer; oxidizing a predetermined portion of the second insulation layer to form a third insulation layer; and etching the third insulation layer, a remaining portion of the second insulation layer, and the first insulation layer to form spacers over sidewalls of the conductive patterns.

### BRIEF DESCRIPTION OF THE DRAWINGS

The above and other objects and features of the present invention will become better understood with respect to the following description of the preferred embodiments given in conjunction with the accompanying drawings, in which:

FIG. 1 illustrates a cross-sectional view of a semiconductor device fabricated by a typical method; and

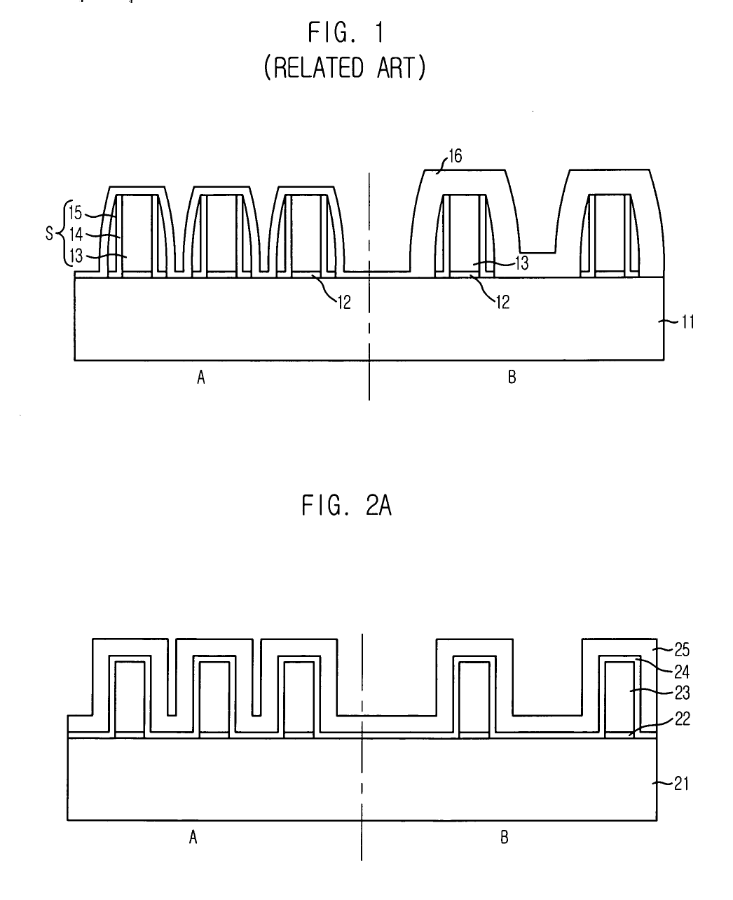

FIGS. 2A to 2C are cross-sectional views illustrating a method for fabricating a semiconductor device in accordance with an embodiment of the present invention.

### DETAILED DESCRIPTION OF THE INVENTION

Hereinafter, detailed descriptions on certain embodiments of the present invention will be provided with reference to the accompanying drawings.

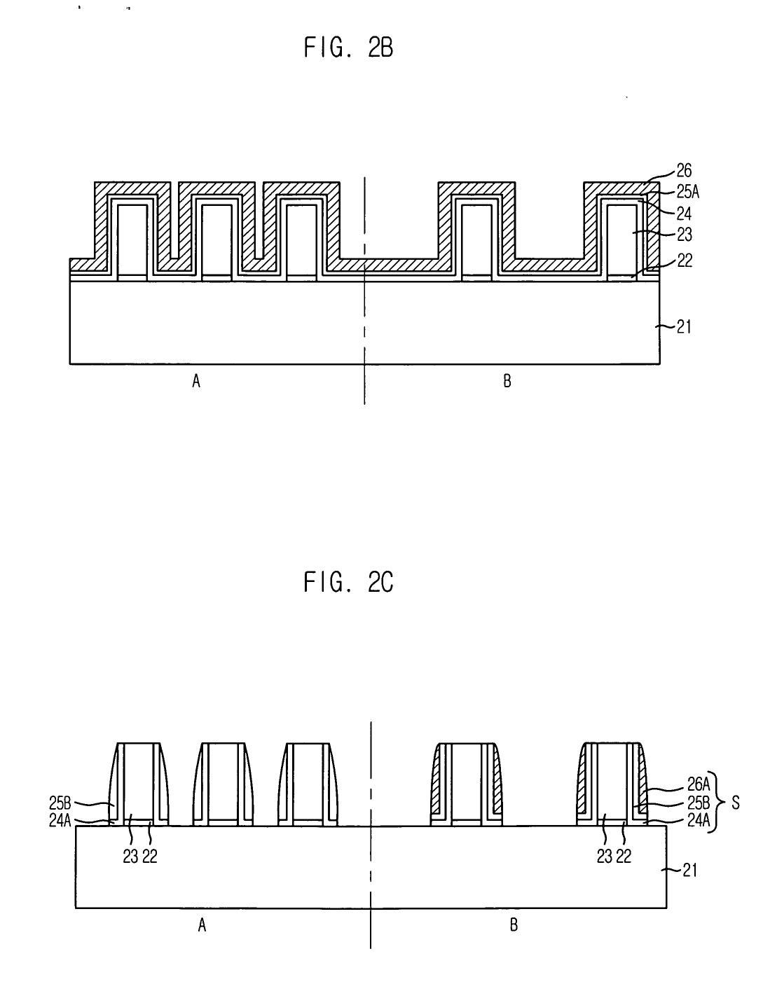

FIGS. 2A to 2C are cross-sectional views illustrating a method for fabricating a semiconductor device in accordance with an embodiment of the present invention.

As shown in FIG. 2A, a plurality of gate patterns, each including a gate insulation layer 22 and a gate electrode 23 in a sequential order are formed over a substrate 21. The substrate 21 is divided into a region A where the gate patterns are densely disposed and a region B where the gate patterns are loosely disposed. For instance, the region A can be referred to as a cell region, and the region B can be referred to as a peripheral region.

A light oxidation process is performed to form a first insulation layer 24 for a first gate spacer. The first insulation layer 24 is a buffer oxide layer which alleviates silicon (i.e., a silicon substrate) damage generated by an implantation process performed to form a junction such as a source/drain region after forming the gate patterns. The first insulation layer 24 ranges from approximately 20 Å to approximately 80 Å.

A second insulation layer 25 is formed over the first insulation layer 24. The second insulation layer 25 is used as a barrier layer to a cleaning solution to remove an oxide-based layer in a subsequent cell region. The second insulation layer 25 is formed with a nitride-based layer having a good step-coverage capability (i.e., a ratio of a deposition thickness X of the bottom disposed between the gate patterns to a deposition thickness Y of sidewalls of the gate patterns is at least approximately 80% or higher). The second insulation layer 25 ranges from approximately 300 Å to approximately 700 Å. The second insulation layer 25 is formed to have a thickness equal to a thickness difference between the first insulation layer 24 and a target spacer.

Since the second insulation layer 25 is formed with a layer having a good step-coverage capability such as SiₓN_{y} or SiₓO_{y}N_{z}, wherein x, y, and z are natural numbers greater than approximately 1, the second insulation layer 25 can be formed with a uniform thickness in the region A and the region B. Accordingly, a thickness difference in spacers typically generated when forming the spacers by using a TEOS layer can be reduced.

As shown in FIG. 2B, a radical oxidation process is performed to oxidize a predetermined portion of the second insulation layer 25. A remaining second insulation layer 25A after being subjected to the radical oxidation process is provided. A thickness of the oxidized portion of the second insulation layer 25 is equal to a thickness to be removed in the cell region through a subsequent process (e.g., a LPC process).

During the radical oxidation process, oxygen (O₂) with a predetermined flow rate is reacted with water (H₂O) or hydrogen (H₂) at a pressure ranging from approximately 0.3 Torr to approximately 1.5 Torr and a temperature ranging from approximately 400° C. to approximately 700° C. In other words, O₂ atoms are reacted with silicon included in the second insulation layer 25 to form a third insulation layer 26 for a second gate spacer. The third insulation layer 26 is a silicon oxide (SiO₂) layer.

As shown in FIG. 2C, the third insulation layer 26, the remaining second insulation layer 25A and the first insulation layer 24 are sequentially etched to form the target spacers S, each including a third insulation pattern 26A, a second insulation pattern 25B and a first insulation pattern 24A in a sequential order on sidewalls of the gate electrode 23.

The third insulation pattern 26A formed in the cell region is removed through a subsequent process (e.g., a LPC process).

As described above, a nitride layer having a good step-coverage capability is formed to have a thickness as substantially the same as a target spacer to reduce a thickness difference in spacers, often caused by gate patterns formed with regionally different densities. A predetermined portion of the nitride layer is oxidized and the oxidized portion of the nitride layer is easily removed performing a cleaning process using buffered oxide etchant (BOE). As a result, a subsequent process such as a LPC process can be easily performed.

Regardless of different densities of the gate patterns, gate spacers have a uniform thickness due to the good step-coverage capability of the nitride layer. Accordingly, a variation of a threshold voltage in a peripheral region can be stably maintained.

According to this embodiment of the present invention, the following effects can be obtained.

First, a nitride layer having a good step-coverage capability is formed to have a thickness as much as a target spacer to reduce a thickness difference in spacers, often caused by the gate patterns formed with regionally different densities. Accordingly, a threshold voltage can be stabilized in a peripheral region by forming spacers having a uniform thickness.

Secondly, a predetermined portion of a nitride layer is oxidized and the oxidized portion of the nitride layer is removed by performing a cleaning process using buffered oxide etchant (BOE). Accordingly, a subsequent process such as a LPC process can be easily performed.

The present application contains subject matter related to the Korean patent application No. KR 2005-0117943, filed in the Korean Patent Office on Dec. 6, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising:
forming a plurality of conductive patterns with regionally different densities over a substrate;
forming a first insulation layer over the conductive patterns;
forming a second insulation layer having substantially the same etch selectivity as the first insulation layer and a better step coverage capability than the first insulation layer over the first insulation layer;
oxidizing a predetermined portion of the second insulation layer to form a third insulation layer; and
etching the third insulation layer, a remaining portion of the second insulation layer, and the first insulation layer to form spacers over sidewalls of the conductive patterns.

2. The method of claim 1, wherein the second insulation layer includes a material having a step-coverage capability of approximately 80% or higher.

3. The method of claim 2, wherein the second insulation layer includes a nitride layer.

4. The method of claim 3, wherein the nitride layer comprises one of SiₓN_{y} and SiₓO_{y}N_{z}, wherein x, y, and z are natural numbers greater than approximately 1.

5. The method of claim 3, wherein the second insulation layer is formed to have a thickness equal to a thickness difference between the first insulation layer and a target spacer.

6. The method of claim 5, wherein the thickness of the second insulation layer ranges from approximately 300 Å to approximately 700 Å.

7. The method of claim 1, wherein the third insulation layer is formed by performing a radical oxidation process.

8. The method of claim 7, wherein the radical oxidation process is performed at a pressure ranging from approximately 0.3 Torr to approximately 1.5 Torr and a temperature ranging from approximately 400° C. to approximately 700° C.

9. The method of claim 8, wherein the radical oxidation process is performed by setting oxygen (O₂) to react with one of water (H₂O) and hydrogen (H₂).

10. The method of claim 3, wherein the first insulation layer is formed by performing a light oxidation process.

11. The method of claim 10, wherein the first insulation layer includes a silicon oxide (SiO₂) layer.

12. A method for fabricating a semiconductor device, comprising:
forming a plurality of conductive patterns having regionally different densities over a substrate;
forming a first insulation layer over the conductive patterns;
forming a second insulation layer having substantially the same etch selectivity to the first insulation layer and a better step-coverage capability than the first insulation layer over the first insulation layer;
oxidizing a predetermined portion of the second insulation layer to form a third insulation layer; and
etching the third insulation layer, a remaining portion of the second insulation layer, and the first insulation layer to form spacers over sidewalls of the conductive patterns.

13. The method of claim 12, wherein the second insulation layer includes a material having a step-coverage capability of approximately 80% or higher.

14. The method of claim 13, wherein the second insulation layer includes a nitride layer.

15. The method of claim 14, wherein the nitride layer comprises one of SiₓN_{y} and SiₓO_{y}N_{z}, wherein x, y, and z are natural numbers greater than approximately 1.

16. The method of claim 14, wherein the second insulation layer is formed to have a thickness equal to a thickness difference between the first insulation layer and a target spacer.

17. The method of claim 16, wherein the second insulation layer ranges from approximately 300 Å to approximately 700 Å.

18. The method of claim 12, wherein the third insulation layer is formed by performing a radical oxidation process.

19. The method of claim 18, wherein the radical oxidation process is performed at a pressure ranging from approximately 0.3 Torr to approximately 1.5 Torr and a temperature ranging from approximately 400° C. to approximately 700° C.

20. The method of claim 19, wherein the radical oxidation process is performed by setting oxygen (O₂) to react with one of water (H₂O) and hydrogen (H₂).

21. The method of claim 12, wherein the first insulation layer is formed by performing a light oxidation process.

22. The method of claim 21, wherein the first insulation layer includes a silicon oxide (SiO₂) layer.
